(19) United States
(12) Patent Application Publication
(10) Pub. No.: US 2020/0067263 A1
(43) Pub. Date: Feb. 27, 2020

(54) METHOD OF MANUFACTURING SEMICONDUCTOR SUBSTRATE

(71) Applicant: FUJI XEROX CO., LTD., Tokyo (JP)

(72) Inventor: Takahiro HASHIMOTO, Ebina-shi (JP)

(73) Assignee: FUJI XEROX CO., LTD., Tokyo (JP)

(21) Appl. No.: 16/505,070

(22) Filed: Jul. 8, 2019

(30) Foreign Application Priority Data
Aug. 21, 2018 (JP) 2018-154548

(51) Int. Cl. H01S 5/028; H01S 5/183; H01S 5/02; H01L 33/00

(52) U.S. Cl. CPC H01S 5/028; H01S 5/18344; H01L 33/0062; H01S 5/0217; H01S 5/0203

(57) ABSTRACT

Provided is a method of manufacturing a semiconductor substrate. The method includes: forming a crushing layer on the back surface of the semiconductor substrate before forming an element on an epitaxial layer formed on a front surface of the semiconductor substrate; and removing a part of the epitaxial layer. The semiconductor substrate is not exposed to a temperature of 200° C. or higher between the forming of the crushing layer and the removing.

### CROSS-REFERENCE TO RELATED APPLICATIONS

This application is based on and claims priority under 35 USC 119 from Japanese Patent Application No. 2018-154548 filed on Aug. 21, 2018

### BACKGROUND

### Technical Field

The present invention relates to a method of manufacturing a semiconductor substrate.

### Related Art

Patent Literature 1 discloses a method of manufacturing a semiconductor substrate, including: a step of forming a first metal film on a first main surface of a semiconductor wafer having a first thickness; a step of performing a back grinding treatment on a second main surface side of the semiconductor wafer to have a second thickness thinner than the first thickness; a step of forming an insulating film pattern including an annular insulating film pattern along a periphery of the second main surface, the insulating film pattern consisting of a first insulating film on the second main surface; a step of setting a thickness of an opening portion of the annular insulating film pattern to a third thickness thinner than the second thickness when the insulating film pattern is present; a step of performing an electric test on the semiconductor wafer when the insulating film pattern is present; a step of holding the second main surface of the semiconductor wafer to a dicing frame via an adhesive sheet bonding the second main surface of the semiconductor wafer when the insulating film pattern is present; and a step of dividing the semiconductor wafer held by a dicing frame into individual chips.

### CITATION LIST

### Patent Literature

Patent Literature 1: Japanese Patent No. 5431777

### SUMMARY

Aspects of non-limiting embodiments of the present disclosure relate to provide a method of manufacturing a semiconductor substrate in which an increase in an amount of warpage of the semiconductor substrate whose warpage is corrected by back surface grinding is prevented in subsequent steps.

Aspects of certain non-limiting embodiments of the present disclosure address the features discussed above and/or other features not described above. However, aspects of the non-limiting embodiments are not required to address the above features, and aspects of the non-limiting embodiments of the present disclosure may not address features described above.

According to an aspect of the present disclosure, there is provided a method of manufacturing a semiconductor substrate according to a first aspect including:

forming a crushing layer on the back surface of the semiconductor substrate before forming an element on an epitaxial layer formed on a front surface of the semiconductor substrate; and

removing a part of the epitaxial layer.

The semiconductor substrate is not exposed to a temperature of 200° C. or higher between the forming of the crushing layer and the removing.

### BRIEF DESCRIPTION OF DRAWINGS

Exemplary embodiment(s) of the present invention will be described in detail based on the following figures, wherein:

FIG. 1 is a process chart showing an example of a method of manufacturing a semiconductor substrate according to a first exemplary embodiment;

FIGS. 2A to 2D are diagrams illustrating a mechanism of warpage of a semiconductor substrate according to the first exemplary embodiment;

FIG. 3 is a graph showing a change in an amount of warpage for each manufacturing step of the method of manufacturing a semiconductor substrate according to the first exemplary embodiment;

FIG. 4 is a process chart showing an example of a method of manufacturing a semiconductor substrate according to a second exemplary embodiment;

FIG. 5 is a graph showing a change in an amount of warpage for each manufacturing step of the method of manufacturing a semiconductor substrate according to the second exemplary embodiment;

FIGS. 6A and 6B are diagrams illustrating an occurrence factor of the warpage and an action of a crushing layer;

FIG. 7A is a diagram illustrating warpage of a semiconductor substrate by grinding according to an exemplary embodiment;

FIG. 7B is a graph showing a relationship between an abrasive grain diameter and an amount of warpage of a finishing grindstone; and

FIG. 8 is a process chart showing an example of a method of manufacturing a semiconductor substrate according to a comparative example.

### DETAILED DESCRIPTION

### First Exemplary Embodiment

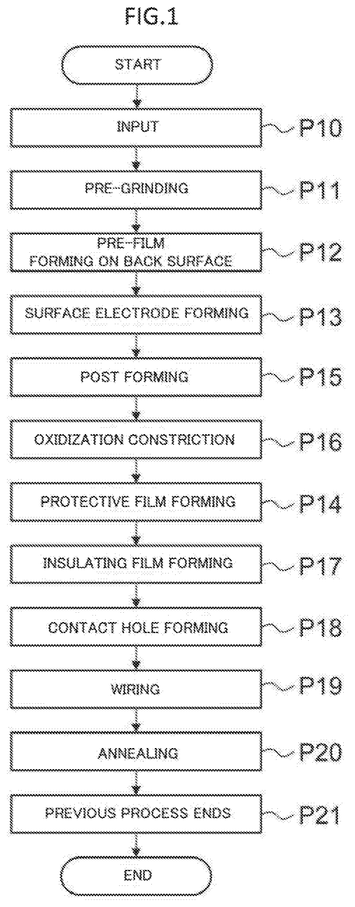

A method of manufacturing a semiconductor substrate according to the first exemplary embodiment will be described in detail with reference to FIGS. 1 to 3. In the following description, an embodiment in which the present invention is applied to a light emitting element such as a GaAs based VCSEL (Vertical Cavity Surface Emitting Laser) will be described as an example.

First, background of a method of manufacturing a semiconductor substrate according to the first exemplary embodiment is described. Along with increasing a diameter of the semiconductor substrate and thinning, warpage of substrate in manufacturing steps (such as conveyance, exposure, and the like) becomes a problem. There are various types of semiconductor elements manufactured by the semiconductor substrate, but in particular, in a case where a semiconductor element is a light emitting element such as a VCSEL, an epitaxial layer may be thick (for example, about a dozen microns), which is particularly a problem. Therefore, there is a demand for a method of correcting warpage in the manufacturing steps. As a method of correcting warpage, there is a method of forming a crushing layer by, for example, grinding on a back surface of the semiconductor substrate before an element is formed on the epitaxial layer (that is, before forming various films, posts, electrodes, wirings, and the like).

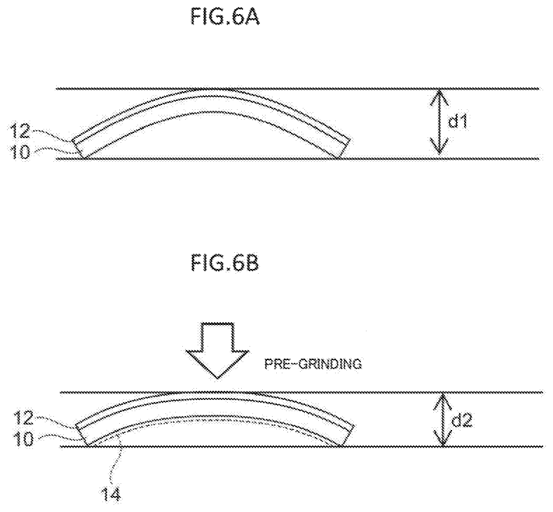

An occurrence factor of the warpage and an action of a crushing layer are described in more detail with reference to FIG. 6. As shown in FIG. 6A, in a stage of forming the epitaxial layer 12 into a film on one surface of a semiconductor substrate 10, the semiconductor substrate 10 warps so that a surface side of the epitaxial layer 12 is convex by a stress of the epitaxial layer 12. Due to a size of the warpage (hereinafter, “warping amount”), trouble occurs in conveyance and the like in the subsequent manufacturing steps. That is, since the warpage is large, there occurs trouble that automatic conveyance cannot be performed. The warpage is relieved as shown in FIG. 6B by forming a crushing layer 14 on the back surface of the substrate before forming the element (referred to as “pre-grinding” in FIG. 6). The “amount of warpage” is a difference between a minimum value and a maximum value of a height of substrate front surface (or the back surface) when the semiconductor substrate 10 is disposed on a flat surface.

That is, when a thickness from the front surface to the back surface including the warpage in the stage of forming the epitaxial layer 12 into a film on one surface of the semiconductor substrate 10 is d1, the thickness is d2 (<d1) by forming the crushing layer 14. This is because the crushing layer 14 is warped so that the back surface side of the semiconductor substrate 10 is in a convex state, so that the warpage of the convex state due to the epitaxial layer 12 is relieved. Hereinafter, a state in which the semiconductor substrate 10 is convex on a surface side of the epitaxial layer 12 is referred to as “upward convex”, and warpage in this direction may be referred to as “upward convex warpage”. Conversely, a state in which a back surface side of the semiconductor substrate 10 is concave is referred to as “downward convex”, and warpage in this direction may be referred to as “downward convex warpage”.

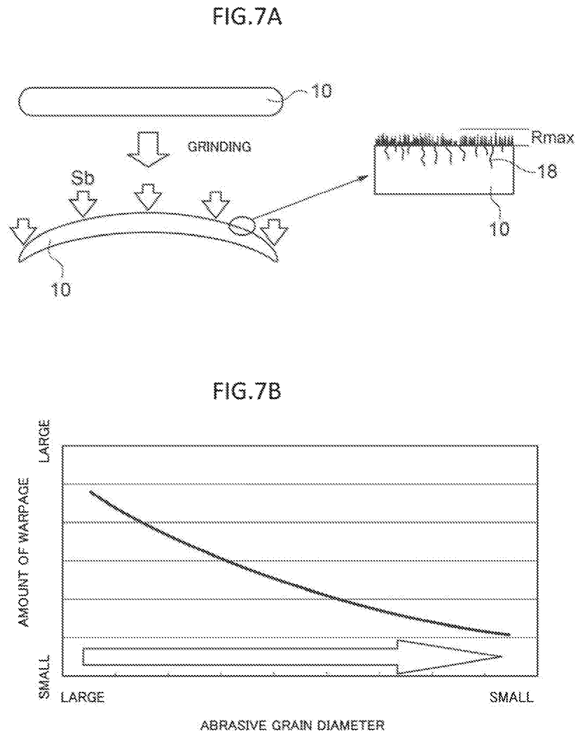

Generation of a stress due to the epitaxial layer 12 is described in more detail with reference to FIG. 7A. FIG. 7A is a diagram conceptually illustrating generation of a stress Sb. As shown in FIG. 7A, when the semiconductor substrate 10 is ground (when the crushing layer 14 is formed), a stress Sb that is a compressive stress is generated on the entire semiconductor substrate 10. The stress Sb causes warpage of the entire semiconductor substrate 10 making a ground surface convex. The compressive stress due to the grinding is generated by occurrence of a grinding damage 18 (crack) on the ground surface side as shown in FIG. 7A. A degree of the grinding damage 18 is indirectly measured by, for example, roughness (maximum height Rₘₐₓ and the like) of the surface of the semiconductor substrate 10.

As described above, “reverse warpage” may occur in the semiconductor substrate 10 depending on the degree of grinding. In the first exemplary embodiment, the “reverse warpage” refers to warpage (that is, downward convex warpage) in which the epitaxial layer 12 is concave. When a degree of forming the crushing layer 14 is large and the compressive stress is large, such inverse warpage may occur. When the amount of warpage due to the crushing layer 14 is set in consideration of subsequent steps, the amount of warpage may also be set so as to be the reverse warpage in this way.

Therefore, in forming the crushing layer 14 for correcting warpage caused by the epitaxial layer 12, it is preferable that a degree of the stress Sb that is the compressive stress is finely adjusted. Therefore, in the first exemplary embodiment, the abrasive grain diameter (grindstone gauge) of the grindstone in grinding for forming the crushing layer 14 is changed according to a correction amount of the warpage.

FIG. 7B shows a relationship between an abrasive grain diameter and an amount of warpage of a finishing grindstone. The horizontal axis shows the abrasive grain diameter and changes from a large side to a small side. In this case, the grindstone gauge changes from small to large. The vertical axis indicates the amount of warpage that occurs when the semiconductor substrates having the same diameter are ground by the same amount (for example, 50 μm) using grindstones having abrasive grain diameters. As shown in FIG. 7B, the amount of warpage that occurs decreases as the abrasive grain diameter decreases. On the other hand, the smaller the abrasive grain diameter is, the more delicate the amount of warpage may be corrected, but grinding time is long. In this manner, the degree of correction of the warpage is adjusted by selection of the abrasive grain diameter, and the semiconductor substrate 10 may be reversely warped if necessary.

Here, other parameters affecting setting of the correction amount of the warpage (selection of the abrasive grain diameter) in the forming of the crushing layer 14 are described. As described above, warpage occurs due to the epitaxial layer 12. An amount of warpage at this time is larger as thickness of the epitaxial layer 12 is larger. The larger the diameter of the semiconductor substrate 10 on which the epitaxial layer 12 is formed and the thinner the thickness is, the larger the amount of warpage is.

On the other hand, after the protective film is formed as described later, the steps proceed, and the epitaxial layer 12 is divided by forming a VCSEL element by etching or the like. At this time, a part of the epitaxial layer 12 is removed. When a part of the epitaxial layer 12 is removed, the compressive stress that generates the warpage is reduced (inversely corrected), so that the amount of warpage is reduced. On the other hand, the thickness of the semiconductor substrate 10 on which the VCSEL element is formed is, for example, 600 μm to 650 μm at first and for example, 500 μm during the steps, and is thinned to for example, about 150 μm finally. The thinning acts in a direction to increase the amount of warpage.

In other words, when in consideration of occurrence of reverse correction and warpage in the subsequent steps, it is not necessary to correct until the semiconductor substrate 10 becomes flat (the amount of warpage less than 10 μm) when the crushing layer 14 for correcting the warpage is formed. Here, the warpage of the semiconductor substrate 10 may cause a suction error in the conveyance step, for example, and may cause bad conveyance. In addition, in an exposure step using a stepper (exposure device) or the like, a focal point is not determined in the plane of the semiconductor substrate 10, which may cause poor focusing. However, even for defects assumed in these subsequent steps, there is an allowable amount of warpage, and the semiconductor substrate 10 is not necessary to be flat. That is, the warpage may be intentionally remained after the forming of the crushing layer 14, and the amount of warpage to be remained may be set to the allowable amount of warpage (target amount of warpage) in the subsequent steps in consideration of the occurrence of reverse correction and warpage in the subsequent steps. In other words, in the subsequent steps after the forming of the crushing layer 14, the warpage may be remained after the forming of the crushing layer 14 so that the warpage does not deteriorate more than the amount of warpage after the forming of the crushing layer 14.

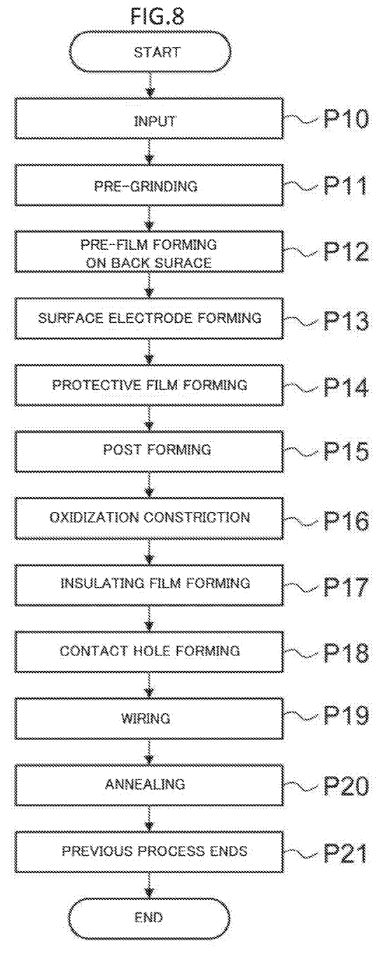

A method of manufacturing a semiconductor substrate according to a comparative example including pre-grinding (forming of a crushing layer) will be described with reference to FIG. 8.

First, in step P10, the GaAs semiconductor substrate 10 on which the epitaxial layer 12 is formed into a film is charged in the manufacturing steps. At this time, in the semiconductor substrate 10, upward convex warpage caused by the epitaxial layer 12 occurs. A temperature at which the semiconductor substrate 10 is exposed in step P10 is room temperature (for example, 23° C.).

Next, pre-grinding is performed in step P11. That is, the back surface of the semiconductor substrate 10 is ground before forming the element and a grinding stress (strain) is applied to the semiconductor substrate 10. Since the back surface grinding causes the downward convex warpage, the upward convex warpage of the semiconductor substrate 10 due to epitaxial growth is relieved depending on a degree of back surface grinding. A temperature at which the semiconductor substrate 10 is exposed is room temperature in step P11.

Next, in step 12, pre-film forming is performed on the back surface. That is, a metal film is formed on the ground surface of the back surface of the semiconductor substrate 10 before forming the element. The metal film has a function of a cover that prevents foreign matter such as shavings of the semiconductor substrate 10 from dropping from the ground surface. Further, since the metal film also functions as a back surface electrode, the metal film is also used for performing for example, an electric inspection such as an in-step inspection. A temperature at which the semiconductor substrate 10 is exposed in step P12 is a vapor deposition temperature, for example, 70° C. to 80° C.

Next, in step P13, a surface electrode is formed. That is, an annular contact metal is formed as an example on a light emission surface of a post upper surface of a VCSEL. More specifically, a mask of the contact metal is formed by photolithography, and the metal is evaporated and lifted off. Here, the “post” according to the first exemplary embodiment refers to a columnar body constituting a light emitting unit, and may be referred to as a “mesa”. A temperature at which the semiconductor substrate 10 is exposed in step P13 is, for example, a photolithographic temperature of 140° C. or lower, and for example, a vapor deposition temperature of 70° C. to 80° C. Here, the temperature of 140° C. in photolithography is a temperature of baking after a resist is applied and exposed.

Next, in step P14, the protective film is formed. That is, the protective film is formed on the light emission surface of the VCSEL. In the protective film forming, as an example, a SiOₓ film (silicon oxide film) is formed on the surface of the semiconductor substrate 10 by CVD (Chemical Vapor Deposition), then a mask is formed by photolithography, and a part of the SiOₓ film is removed by dry etching and patterned. Here, when a SiOₓ film is formed on the semiconductor substrate, the upward convex warpage occurs. A temperature at which the semiconductor substrate 10 is exposed in step P14 is, for example, a photolithographic temperature of 140° C. or lower, and for example, a CVD film forming temperature of 300° C. to 400° C.

Next, post forming is performed in step P15, which is an example of the removing step. That is, after the mask is formed by photolithography, a part of the epitaxial layer 12 formed on the semiconductor substrate 10 is removed by, for example, dry etching to form a post (mesa) of the VCSEL. A temperature at which the semiconductor substrate 10 is exposed in step P15 is, for example, a photolithographic temperature of 140° C. or lower, and for example, a dry etching temperature of 40° C. or lower.

Next, oxidation constriction is performed in step P16. That is, the semiconductor substrate 10 is placed in an oxidation furnace, the post of the VCSEL is oxidized from a side by water vapor heating to form a current constriction structure. A temperature at which the semiconductor substrate 10 is exposed in step P16 is, for example, a temperature of a heating furnace of 400° C. or lower.

Next, in step P17, an insulating film is formed. That is, a SiN film (silicon nitride film) is formed as an example on the surface of the semiconductor substrate 10 by CVD. A temperature at which the semiconductor substrate 10 is exposed in step P17 is, for example, a CVD film forming temperature of 300° C. to 400° C.

Next, in step P18, a contact hole formed. That is, a mask is formed by photolithography, and a part of the SiN film formed in step P17 is removed by for example, dry etching and patterned. Here, since the protective film of a light emission port using the SiOₓ film is formed in the protective film forming (step P14), the SiN film formed on the protective film by CVD is removed by etching. A temperature at which the semiconductor substrate 10 is exposed in step P18 is, for example, a photolithographic temperature of 140° C. or lower, and for example, a dry etching temperature of 40° C. or lower.

Next, in step P19, wiring is formed. That is, a mask for wiring is formed by photolithography, metal is evaporated, and then lift-off is performed to form wiring. A temperature at which the semiconductor substrate 10 is exposed in step P19 is, for example, a photolithographic temperature of 140° C. or lower, and for example, a vapor deposition temperature of 70° C. to 80° C.

Next, annealing is performed in step P20. That is, the semiconductor substrate 10 is charged in a heating furnace to perform heat treatment in order to make ohmic contact with the electrode on the front surface and the electrode on the back surface of the semiconductor substrate 10. A temperature at which the semiconductor substrate 10 is exposed in step P20 is, for example, an annealing temperature of 450° C. or lower.

Then, the previous process ends (P21) Here, the “previous process” means the previous step of the method of manufacturing a semiconductor substrate. In the subsequent steps with respect to the previous step, a dicing step of dividing the semiconductor substrate 10 into individual semiconductor elements, back surface processing including thinning grinding, back surface electrode forming, and the like, electric characteristic inspection, appearance inspection, and the like of the semiconductor element are performed.

As described above, in the manufacturing steps of the semiconductor substrate according to the comparative example, the pre-grinding is performed in step P11, so that the upward convex warpage of caused by the epitaxial layer 12 may be reduced, and thus trouble in steps such as exposure after step P12 is prevented.

However, even if the crushing layer is formed by the pre-grinding, when the semiconductor substrate 10 is exposed to a high temperature of a certain temperature or higher in the subsequent steps, the downward convex warpage by the crushing layer is relieved, and the warpage may be returned to an original state, that is, a state close to warpage at the time of charging of step P10. Therefore, in the first exemplary embodiment, the semiconductor substrate 10 is not exposed to a high temperature of a certain temperature or higher before the epitaxial layer is processed to form the element. Accordingly, a method of manufacturing a semiconductor substrate is provided, in which an increase in an amount of warpage of the semiconductor substrate whose warpage is corrected by back surface grinding in a later step is prevented. In the first exemplary embodiment, “before forming an element” refers to before post forming of step P15.

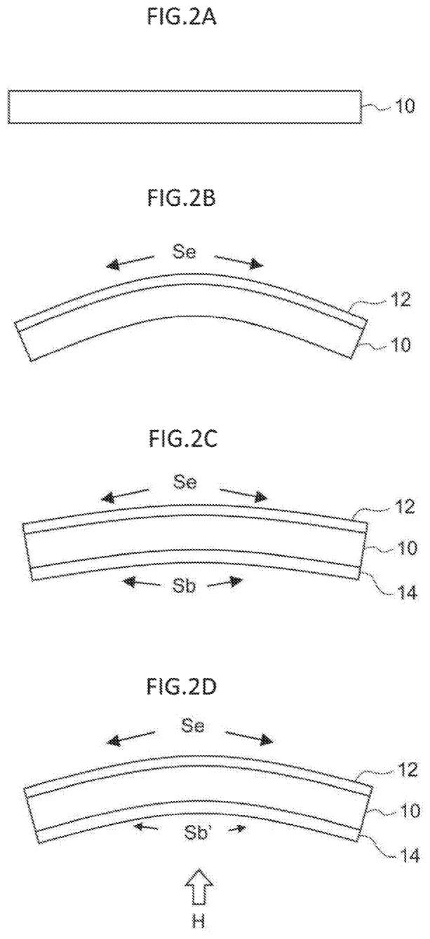

Here, a mechanism of occurrence of the warpage of the semiconductor substrate is described in more detail with reference to FIGS. 2A to 2D. FIG. 2A shows the semiconductor substrate 10 (a GaAs wafer in the first exemplary embodiment) without performing any treatment. As shown in FIG. 2A, the semiconductor substrate 10 is flat without warpage. FIG. 2B shows a state in which the epitaxial layer 12 is grown on the semiconductor substrate 10. As shown in FIG. 2B, the upward convex warpage occurs in the semiconductor substrate 10. This is because a stress Se due to the epitaxial layer 12 acts in a direction of spreading the epitaxial layer 12.

On the other hand, FIG. 2C shows a state in which pre-grinding (forming of a crushing layer) is performed on the back surface of the semiconductor substrate 10 in a state shown in FIG. 2B. A strain occurs on the back surface of the semiconductor substrate 10 by the pre-grinding. The strain due to the pre-grinding causes the stress Sb, and the stress Sb acts in a direction of spreading the ground surface, that is, in a direction opposite to the stress Se due to the epitaxial layer 12. Then, the stress Se due to the epitaxial layer 12 is at least partially offset against the stress Sb due to the pre-grinding. As a result, the upward convex warpage due to the epitaxial layer 12 is reduced.

FIG. 2D shows a state in which the semiconductor substrate 10 in the state of FIG. 2C is further exposed to a high temperature H (a state in which heat treatment is performed). When the semiconductor substrate 10 in which the upward convex warpage is relieved by the pre-grinding is exposed to the high temperature H, the strain due to the pre-grinding is removed or relieved as shown in FIG. 2D. That is, the stress Sb due to the pre-grinding is a stress Sb′ (<Sb), and the stress Se due to the epitaxial layer 12 becomes dominant. That is, the upward convex warpage of the semiconductor substrate 10 returns to a level which becomes a problem.

It is described that when the semiconductor substrate 10 after the pre-grinding is exposed to a high temperature, the stress due to the pre-grinding is removed or relieved as follows. That is, since the grinding pressure Sb relates to the semiconductor substrate 10 during the pre-grinding, a strain due to work hardening occurs. The strain due to the work hardening is generally removed by a heat treatment called annealing. That is, it is described that when the semiconductor substrate 10 after the pre-grinding is exposed to a high temperature, the semiconductor substrate 10 becomes soft, and the stress due to the pre-grinding is removed or relieved by a principle that the hardened portion is leveled.

Next, a method of manufacturing a semiconductor substrate according to the first exemplary embodiment will be described with reference to FIG. 1. Although FIG. 1 is a process chart showing a step flow of the method of manufacturing a semiconductor substrate according to the first exemplary embodiment, the same steps are denoted by the same step signs as those in the method of manufacturing a semiconductor substrate according to the comparative example shown in FIG. 8, and detailed description thereof is omitted.

As is clear from comparison between FIG. 1 and FIG. 8, a position of step P14 of protective film forming is changed in the method of manufacturing a semiconductor substrate according to the first exemplary embodiment. That is, although the protective film forming step is performed before post forming of step P15 after surface electrode forming of step P13 in the comparative example, this is changed so as to perform the protective film forming step before insulating film forming of step P17 after oxidization constriction step of step P16.

A reason for the change is as follows. That is, as a result of study due to experiments or the like, it is found that the downward convex warpage given in the pre-grinding (crushing layer forming) of step P11 begins to return from about 200° C. That is, it is known that the photolithographic temperature of about 140° C. does not affect the downward convex warpage much. It is found that when the temperature exceeds 300° C., a ratio of the downward convex warpage that returns increases. On the other hand, when the post is formed in step P15, a part of the epitaxial layer 12 is removed, so that the upward convex warpage is relieved. That is, after the post forming, an influence of the upward convex warpage is reduced, and it is difficult to return to the original. Therefore, an influence of a high temperature step prior to the post forming of step P15 is reduced in the first exemplary embodiment.

That is, a step of exposing the semiconductor substrate 10 to a high temperature of 200° C. or higher (or 300° C. or higher) in a step prior to the post forming of step P15 of the step shown in FIG. 8 is a protective film forming step of step P14. In the protective film forming step, as described above, the semiconductor substrate 10 is exposed to a temperature of 300° C. to 400° C. in the CVD film forming step. Therefore, a position of the protective film forming step of step P14 is changed after the oxidation constriction step of step P16 in the first exemplary embodiment.

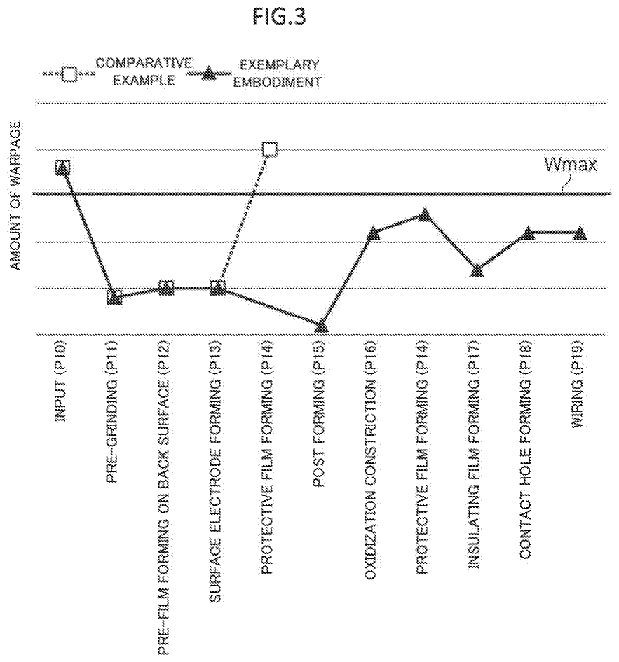

A change in the amount of warpage in the method of manufacturing a semiconductor substrate according to the first exemplary embodiment will be described with reference to FIG. 3. FIG. 3 is a graph showing each step in the horizontal axis and showing the amount of warpage after performing each step with a solid line in the vertical axis. For the amount of warpage, a direction toward a paper surface of the vertical axis is a direction of the upward convex warpage. That is, for the amount of warpage, warpage in a direction defined by d1 (d2) shown in FIG. 6 is warpage in a positive (+) direction. In FIG. 3, a result of the method of manufacturing a semiconductor substrate according to the comparative example is shown by a dotted line for comparison. A sign “Wₘₐₓ” shown in FIG. 3 indicates a maximum amount of warpage (hereinafter referred to as “maximum amount of warpage”) that is not a problem in steps such as exposure. That is, in the first exemplary embodiment, it is a target that an amount of warpage is less than Wₘₐₓ in each stage of the manufacturing steps.

As shown in FIG. 3, the upward convex warpage depending on a state of the epitaxial layer 12 occurs in the semiconductor substrate 10 at the time of charging (step P10). When pre-grinding is performed to the semiconductor substrate 10 at the time of charging (step P11), the upward convex warpage is relieved. Thereafter, the amount of warpage does not change greatly even after the pre-film forming on the back surface (step P12) and the surface electrode forming (step P13). This is because the temperature at which the semiconductor substrate 10 is exposed in the pre-film forming on the back surface is a vapor deposition temperature of 70° C. to 80° C., and a highest temperature to which the semiconductor substrate 10 is exposed in the surface electrode forming is a photolithographic temperature of 140° C. or lower. Until this step, the method of manufacturing a semiconductor substrate according to the comparative example as shown in FIG. 3, the method of manufacturing a semiconductor substrate according to the first exemplary embodiment have no great difference in warpage.

Next, in the method of manufacturing a semiconductor substrate according to the comparative example in which the protective film is formed (step P14), the downward convex warpage due to the crushing layer is relieved, and the upward convex warpage suddenly increases as shown in FIG. 3. The reason is that the semiconductor substrate 10 is exposed to a temperature of 300° C. to 400° C. during the CVD film forming in the protective film forming step as described above, the maximum amount of warpage Wₘₐₓ is exceeded in some cases, and it is difficult to perform subsequent steps such as exposure. Even in a case where the maximum amount of warpage Wₘₐₓ is not exceeded, the amount of warpage increases, so that an effect in the pre-grinding is reduced.

In contrast, in the method of manufacturing a semiconductor device according to the first exemplary embodiment, the protective film forming (step 14) is not performed at this time, and changes to the post forming (step P15), which is an example of the removing step. Since the post forming is performed by removing a part of the epitaxial layer 12, the upward convex warpage is somewhat relieved, and as shown in FIG. 3, warpage in the downward convex direction increases after the post forming. Why the increase in the upper concave warpage in the next oxidation constriction (step P16) is that a temperature at which the semiconductor substrate 10 is exposed in the oxidation constriction (step P16) is a temperature of a heating furnace of 400° C. or lower as described above. However, in the first exemplary embodiment, since the post forming (step P15) is performed before the oxidation constricting step, an influence of a high temperature is relieved, and the amount of warpage is kept less than the maximum amount of warpage Wₘₐₓ.

In the first exemplary embodiment, the protective film forming (step P14), which is a skipped step next, is performed after step P16. In the protective film forming step, the semiconductor substrate 10 is exposed to a high temperature (300° C. to 400° C.) of the CVD film forming, but since a part of the epitaxial layer 12 is removed in the post forming (step P15) and the semiconductor substrate 10 is exposed to a high temperature once in the oxidation constriction (step P16), the increase in the upward convex warpage is kept low.

Thereafter, the insulating film forming (step P17), the contact hole forming (step P18), and the wiring forming (step P19) follow, but an increase or decrease amount of warpage is small and the amount of warpage is kept less than the maximum amount of warpage Wₘₐₓ. Here, in the insulating film forming (step P17), the downward convex warpage is increased, but this is because the downward convex warpage intentionally occurs and the upward convex warpage is relieved. That is, in the insulating film forming using the SiN (silicon nitride film) according to the first exemplary embodiment (step P17), a direction of warpage after film forming may be controlled. The direction of warpage is controlled by controlling a flow rate of raw materials. In other words, the direction of warpage and the amount of warpage in the insulating film forming (step P17) may be set in consideration of the direction of warpage and the amount of warpage to the insulating film forming (step P17). On the other hand, the amount of the upward convex warpage after the contact hole forming (step P18) is because a part of the insulating film is removed in the step.

### Second Exemplary Embodiment

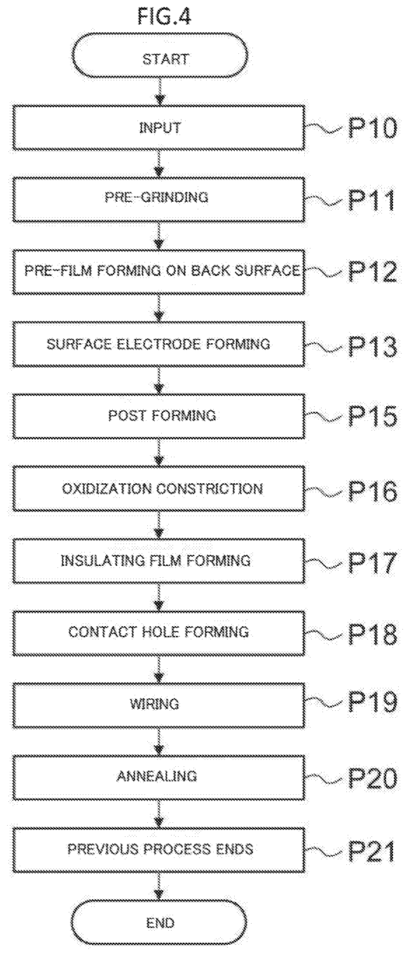

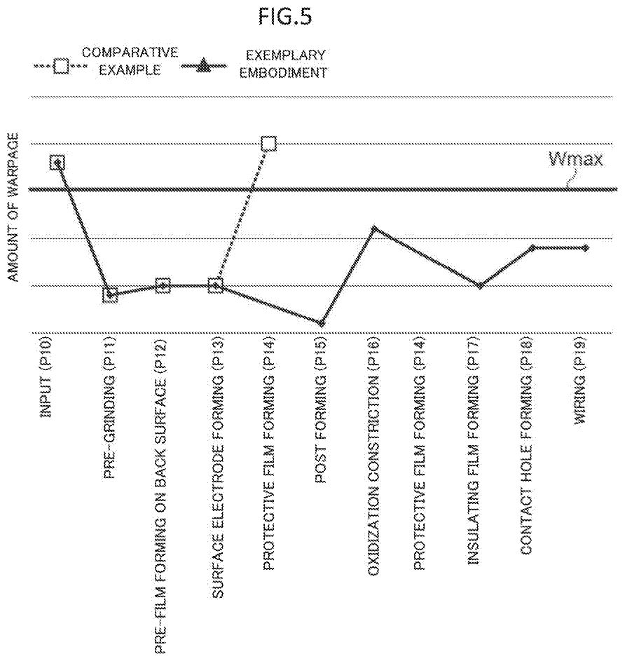

A method of manufacturing a semiconductor substrate according to the second exemplary embodiment will be described with reference to FIGS. 4 and 5. The second exemplary embodiment is an embodiment in which the protective film forming (step P14) is combined with the insulating film forming (step P17) in the first exemplary embodiment. Therefore, the same steps as that of the first exemplary embodiment are denoted by the same signs, and detailed description is omitted.

A step flow of the method of manufacturing a semiconductor substrate according to the second exemplary embodiment will be described with reference to FIG. 4. As is clear from comparison between FIG. 1 and FIG. 4, the protective film forming (step P14) is removed in the step flow according to the second exemplary embodiment. However, the protective film is formed simultaneously with the insulating film in the insulating film forming (step P17) rather than not forming the protective film of the light emission port of the VCSEL in the second exemplary embodiment. That is, the SiN film including the light emission port is formed by CVD, and the protective film is patterned simultaneously with the next contact hole forming (step P18) in the second exemplary embodiment. That is, although the protective film is formed of the SiOₓ film in the first exemplary embodiment, the protective film is formed of the SiN film in the second exemplary embodiment. Although the SiOₓ film and the SiN film have different refractive indexes, there is no significant difference in characteristics when viewed as a protective film. The SiOₓ film or the SiN film may be selected in consideration of, for example, a position in the manufacturing steps or the like, and for example, when a protective film is desired to be formed at an early stage of the manufacturing steps, the protective film using the SiOₓ film may be selected.

FIG. 5 shows the amount of warpage of a substrate in the manufacturing steps of the semiconductor substrate according to the second exemplary embodiment. In FIG. 5, the amount of warpage until the oxidation constriction (step P16) is the same as the amount of warpage according to the above exemplary embodiment shown in FIG. 3. On the other hand, the insulating film forming (step P17) is performed after the oxidation constriction (step P16) in the second exemplary embodiment. As shown in FIG. 5, a direction of warpage of the insulating film forming (step P17) is adjusted to be downward convex in the second exemplary embodiment. The amounts of warpage of subsequent contact hole forming (step P18) and wiring forming (step P19) show the same tendency as in FIG. 3. As a result, the amount of warpage of the semiconductor substrate 10 is kept less than the maximum amount of warpage Wₘₐₓ by the method of manufacturing a semiconductor substrate according to the second exemplary embodiment.

Here, the temperature at which the semiconductor substrate 10 is exposed in each step according to each of the above exemplary embodiments is summarized. As described above, when the temperature at which the semiconductor substrate 10 is exposed to 200° C. or higher, the downward convex warpage due to a crushing layer starts to be relieved, so that it is necessary to not expose the semiconductor substrate 10 to a temperature of 200° C. or higher before the post forming (step P15, that is, forming of an element). However, when it is difficult to divide the steps at 200° C., the semiconductor substrate 10 may not be exposed to a temperature of 300° C. or higher at which the downward convex warpage due to the crushing layer is relieved suddenly. Further, when considered in steps, since a CVD film forming step at 300° C. or higher is necessary to be considered in each of the above exemplary embodiments, the CVD film forming step may not be performed before the post forming.

Although the post forming (step P15) is exemplified as an example of the removing step in each of the above exemplary embodiments, but the removing step is not limited thereto. In a step order of the post forming, a step of forming a concave portion unrelated to the post forming may be performed before the protective film forming (step P14) as an example of the removing step after the protective film forming (step P14) same as the comparative example of FIG. 8.

Although the VCSEL is described as an example of an element to be formed on the semiconductor substrate in each of the above exemplary embodiments, the element is not limited to a laser element such as a VCSEL, and may be applied to a III-V compounds semiconductor substrate for forming a light emitting element including a light emitting diode, a light emitting thyristor, and the like. In particular, since the epitaxial layer is thick in the light emitting element having a semiconductor multilayer film, the amount of warpage tends to increase. Therefore, the second exemplary embodiment is preferably applied to the III-V compounds semiconductor substrate having a semiconductor multilayer film as an example. The larger the size of the semiconductor substrate is, the larger the amount of warpage is. Therefore, the III-V compounds semiconductor substrate is preferably applied to a compound semiconductor substrate having a size of 6 inches or exceeding 6 inches. The second exemplary embodiment is not limited to the compound semiconductor substrate, and may be applied to a silicon semiconductor substrate.

In each of the above exemplary embodiments, the amount of warpage before an element is formed on the epitaxial layer may be applied to a semiconductor substrate not exceeding the amount of warpage allowed in the manufacturing steps, or may be applied to a semiconductor substrate in which the amount of warpage before the element is formed on the epitaxial layer exceeds the amount of warpage allowed in the manufacturing steps. In the former case, the manufacturing steps may flow when the amount of warpage is smaller; and in the latter case, a semiconductor substrate not allowed in the manufacturing steps is allowed.

A maximum value of the amount of warpage of the semiconductor substrate allowed in the manufacturing steps is generally about 150 μm to 250 μm, and the amount of warpage of the semiconductor substrate may also be about the same amount of warpage. Therefore, a correction amount (difference) of the warpage is 50 μm or more, preferably 100 μm or more. As an example, each of the above exemplary embodiments is applied to a semiconductor substrate in which the amount of warpage before the element is formed on the epitaxial layer exceeds 150 μm, and the amount of warpage of 100 μm or less is preferable. As another example, each of the above exemplary embodiments is applied to a semiconductor substrate in which the amount of warpage before the element is formed on the epitaxial layer exceeds 200 μm, and the amount of warpage of 100 μm or less or 150 μm or less is preferable. As another example, each of the above exemplary embodiments is applied to a semiconductor substrate in which the amount of warpage before the element is formed on the epitaxial layer exceeds 250 μm, and the amount of warpage of 100 μm or less, 150 μm or less, or 200 μm or less is preferable.

Further, in order to correct warpage of the semiconductor substrate regardless of whether or not the semiconductor substrate is exposed to a temperature of 200° C. or higher of the CVD film forming or the like between the crushing layer forming step and the removing step, the crushing layer forming step described in each of the above exemplary embodiments may be applied.

As another example, before the light emitting element is formed on the epitaxial layer formed on the front surface of the semiconductor substrate having an amount of warpage exceeding 150 μm, a method of manufacturing a semiconductor substrate that forms a crushing layer on the back surface of the semiconductor substrate may be used so that the amount of warpage is 100 μm or less.

As another example, before the light emitting element is formed on the epitaxial layer formed on the front surface of the semiconductor substrate having an amount of warpage exceeding 200 μm, a method of manufacturing a semiconductor substrate that forms a crushing layer on the back surface of the semiconductor substrate may be used so that the amount of warpage is 100 μm or less.

As another example, before the light emitting element is formed on the epitaxial layer formed on the front surface of the semiconductor substrate having an amount of warpage exceeding 250 μm, a method of manufacturing a semiconductor substrate that forms a crushing layer on the back surface of the semiconductor substrate may be used so that the amount of warpage is 100 μm or less.

According to the above, the amount of warpage of the semiconductor substrate is corrected to 100 μm or less.

As another example, before the light emitting element is formed on the epitaxial layer formed on the front surface of the semiconductor substrate having an amount of warpage exceeding 200 μm, a method of manufacturing a semiconductor substrate that forms a crushing layer on the back surface of the semiconductor substrate may be used so that the amount of warpage is 150 μm or less.

As another example, before the light emitting element is formed on the epitaxial layer formed on the front surface of the semiconductor substrate having an amount of warpage exceeding 250 μm, a method of manufacturing a semiconductor substrate that forms a crushing layer on the back surface of the semiconductor substrate may be used so that the amount of warpage is 150 μm or less.

According to the above, the amount of warpage of the semiconductor substrate is corrected to 150 μm or less.

As another example, before the light emitting element is formed on the epitaxial layer formed on the front surface of the semiconductor substrate having an amount of warpage exceeding 250 μm, a method of manufacturing a semiconductor substrate that forms a crushing layer on the back surface of the semiconductor substrate may be used so that the amount of warpage is 200 μm or less. According to the above, the amount of warpage of the semiconductor substrate is corrected to 200 μm or less.

As another example, before the light emitting element is formed on the epitaxial layer formed on the front surface of the semiconductor substrate having an amount of warpage exceeding a specified value of the manufacturing steps, a method of manufacturing a semiconductor substrate that forms a crushing layer on the back surface of the semiconductor substrate may be used so that the amount of warpage is equal to or less than the specified value. According to the above, the amount of warpage of the semiconductor substrate is corrected to be equal to or less than the specified value.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A method of manufacturing a semiconductor substrate, comprising:
forming a crushing layer on the back surface of the semiconductor substrate before forming an element on an epitaxial layer formed on a front surface of the semiconductor substrate; and
removing a part of the epitaxial layer,
wherein the semiconductor substrate is not exposed to a temperature of 200° C. or higher between the forming of the crushing layer and the removing.

2. A method of manufacturing a semiconductor substrate according to claim 1,
wherein the removing includes forming a mesa structure constituting the element by etching the epitaxial layer.

3. A method of manufacturing a semiconductor substrate according to claim 2,
wherein the mesa structure constitutes a vertical cavity surface emitting laser element.

4. A method of manufacturing a semiconductor substrate according to claim 1,
wherein the element is a light emitting element, and
the method further comprises forming a protective film that protects a light emission port of the light emitting element after the removing.

5. A method of manufacturing a semiconductor substrate according to claim 4,
wherein the removing includes forming a mesa structure constituting the element by etching the epitaxial layer, and
the forming of the protective film is performed after the forming of the mesa structure.

6. A method of manufacturing a semiconductor substrate according to claim 5, further comprising forming an insulating film covering a part of the mesa structure, in which the protective film is formed at the same time.

7. A method of manufacturing a semiconductor substrate according to claim 1,
wherein the semiconductor substrate is not exposed to a temperature of 300° C. or higher between the forming of the crushing layer and the removing.

8. A method of manufacturing a semiconductor substrate comprising:
forming a crushing layer on the back surface of the semiconductor substrate before forming an element on an epitaxial layer formed on a front surface of the semiconductor substrate; and
removing a part of the epitaxial layer, wherein
the method is not provided with forming a film on the semiconductor substrate by chemical vapor deposition between the forming of the crushing layer and the removing.

9. A method of manufacturing a semiconductor substrate according to claim 8,
wherein the removing includes forming a mesa structure constituting the element by etching the epitaxial layer.

10. A method of manufacturing a semiconductor substrate according to claim 9,
wherein the mesa structure constitutes a vertical cavity surface emitting laser element.

11. A method of manufacturing a semiconductor substrate according to claim 8,
wherein the element is a light emitting element, and
the method further comprises forming a protective film that protects a light emission port of the light emitting element after the removing.

12. A method of manufacturing a semiconductor substrate according to claim 11,
wherein the removing includes forming a mesa structure constituting the element by etching the epitaxial layer, and
the forming of the protective film is performed after the forming of the mesa structure.

13. A method of manufacturing a semiconductor substrate according to claim 12, further comprising forming an insulating film covering a part of the mesa structure, in which the protective film is formed at the same time.

14. A method of manufacturing a semiconductor substrate according to claim 8,
wherein the semiconductor substrate is not exposed to a temperature of 200° C. or higher between the forming of the crushing layer and the removing.

15. A method of manufacturing a semiconductor substrate according to claim 8,
wherein the semiconductor substrate is not exposed to a temperature of 300° C. or higher between the forming of the crushing layer and the removing.

16. A method of manufacturing a semiconductor substrate according to claim 2,
wherein the element is a light emitting element, and
the method further comprises forming a protective film that protects a light emission port of the light emitting element after the removing.

17. A method of manufacturing a semiconductor substrate according to claim 3,
wherein the element is a light emitting element, and
the method further comprises forming a protective film that protects a light emission port of the light emitting element after the removing.

18. A method of manufacturing a semiconductor substrate according to claim 2,
wherein the semiconductor substrate is not exposed to a temperature of 300° C. or higher between the forming of the crushing layer and the removing.

19. A method of manufacturing a semiconductor substrate according to claim 3,
wherein the semiconductor substrate is not exposed to a temperature of 300° C. or higher between the forming of the crushing layer and the removing.

20. A method of manufacturing a semiconductor substrate according to claim 4,
wherein the semiconductor substrate is not exposed to a temperature of 300° C. or higher between the forming of the crushing layer and the removing.
